(19) United States
(12) Patent Application Publication
(10) Pub. No.: US 2026/0167866 A1
(43) Pub. Date: Jun. 18, 2026

(54) COMPOSITION FOR ETCHING SILICON

(71) Applicant: DONGWOO FINE-CHEM CO., LTD., Iksan-si (KR)

(72) Inventors: Gi Woo LEE, Iksan-si (KR); Myeongil Jeong, Iksan-si (KR)

(73) Assignee: DONGWOO FINE-CHEM CO., LTD., Iksan-si (KR)

(21) Appl. No.: 19/410,327

(22) Filed: Dec. 5, 2025

(30) Foreign Application Priority Data
Dec. 13, 2024 (KR) 10-2024-0185919

(51) Int. Cl. C09K 13/00; H10P 50/66

(52) U.S. Cl. CPC C09K 13/00; H10P 50/667

(57) ABSTRACT

The present invention provides a composition for etching silicon comprising an alkaline compound, a carboxylic acid compound, an alcohol-based additive, and water. The composition for etching silicon according to the present invention can rapidly etch silicon films while protecting SiO₂ and SiN, and exhibit excellent etching uniformity.

### CROSS REFERENCE TO RELATED APPLICATIONS

This application claims priority based on Korean Patent Application No. 10-2024-0185919, filed Dec. 13, 2024, the entire content of which is incorporated herein by reference in its entirety.

### TECHNICAL FIELD

The present invention relates to a composition for etching silicon, more specifically to a composition for etching silicon that rapidly etches silicon films while protecting SiO₂ and SiN, and exhibits excellent etching uniformity.

### BACKGROUND ART

In semiconductor devices such as DRAM, NAND flash memory devices, and logic devices, development continues to rapidly reduce critical dimensions (CD) while achieving high capacity.

In these semiconductor devices, silicon-based films or patterns, such as polysilicon, are widely used as materials for gate electrodes, capacitor electrodes, conductive contacts, wiring, and so on. When gate electrodes or wiring are formed by direct etching of metal films, achieving patterns with desired fine dimensions is challenging due to etching resolution limitations. Consequently, processes utilizing polysilicon films are being researched.

Meanwhile, to manufacture a NAND with many layers, a SiN layer and a SiO₂ layer are coated, followed by creating holes through a dry process, depositing polysilicon, and then stacking another SiN layer and SiO₂ layer. Subsequently, after depositing the desired layer, the polysilicon film is finally removed.

Therefore, technological development is required for a composition for etching silicon to remove the polysilicon film.

For example, Korean Patent Publication No. 10-2021-0053083 proposes a composition for etching polysilicon comprising phosphorus-containing acid and cyclic alcohol.

To achieve high-reliability semiconductor device fabrication, it is essential to secure a high etch rate for the target material and achieve excellent etching uniformity. Furthermore, during silicon film etching processes, it is necessary to suppress etching of protective layers such as SiN and SiO₂ layers and protect them.

### DISCLOSURE

### Technical Problem

An object of the present invention is to provide a composition for etching silicon that rapidly etches silicon films while protecting SiO₂ and SiN, and exhibits excellent etching uniformity.

Another object of the present invention is to provide a method for forming a pattern using the above composition for etching silicon.

### Technical Solution

According to an aspect, the present invention provides a composition for etching silicon comprising an alkaline compound, a carboxylic acid compound, an alcohol-based additive, and water.

In one embodiment of the present invention, the alkaline compound may comprise a quaternary alkyl ammonium salt compound.

In one embodiment of the present invention, the quaternary alkyl ammonium salt compound may be one or more selected from the group consisting of tetramethylammonium hydroxide, ethyl trimethylammonium hydroxide, diethyl dimethylammonium hydroxide, tetraethyl ammonium hydroxide, tetrapropylammonium hydroxide, tetrabutylammonium hydroxide, tetrapentylammonium hydroxide, and tetrahexylammonium hydroxide.

In one embodiment of the present invention, the carboxylic acid compound may be one or more selected from the group consisting of formic acid, acetic acid, propionic acid, butyric acid, palmitic acid, stearic acid, oleic acid, oxalic acid, malonic acid, succinic acid, tartaric acid, maleic acid, glycolic acid, glutaric acid, adipic acid, sulfosuccinic acid, valeric acid, caproic acid, caprylic acid, capric acid, lauric acid, myristic acid, lactic acid, malic acid, citric acid, benzoic acid, salicylic acid, naphthoic acid, nicotinic acid, toluic acid, anisic acid, cumic acid, phthalic acid, and salts thereof.

In one embodiment of the present invention, the carboxylic acid compound may have one or more hydroxyl groups.

In one embodiment of the present invention, the alcohol-based additive may be one or more selected from the group consisting of a monoalcohol having 1 to 4 carbon atoms, alkylene glycol ether having 2 to 4 carbon atoms, and alkylene glycol having 2 to 4 carbon atoms.

The composition for etching silicon according to one embodiment of the present invention may comprise 0.1 to 10 wt % of the alkaline compound, 0.1 to 20 wt % of the carboxylic acid compound, 0.00001 to 0.1 wt % of the alcohol-based additive, based on the total weight of the composition, and a residual amount of water to bring the total weight of the composition to 100 wt %.

The composition for etching silicon according to one embodiment of the present invention may not contain an oxidizing agent.

The composition for etching silicon according to one embodiment of the present invention may not contain a surfactant.

The composition for etching silicon according to one embodiment of the present invention may not contain an azole compound.

The composition for etching silicon according to one embodiment of the present invention may not contain a thiol compound.

The composition for etching silicon according to one embodiment of the present invention may not contain a fluoride.

The composition for etching silicon according to one embodiment of the present invention may have a pH of 10 or higher at 25° C.

According to another aspect, the present invention provides a method for forming a pattern comprising etching a silicon film using the above composition for etching silicon.

### Advantageous Effects

The composition for etching silicon according to the present invention can rapidly etch silicon films while protecting SiO₂ and SiN, and exhibit excellent etching uniformity.

### BEST MODE

Hereinafter, the present invention will be described in more detail.

One embodiment of the present invention relates to a composition for etching silicon comprising an alkaline compound (A), a carboxylic acid compound (B), an alcohol-based additive (C), and water (D).

In the composition for etching silicon according to one embodiment of the present invention, hydroxide anion (OH⁻) of the alkaline compound reacts with silicon in the silicon film to form a silanol (Si—OH) structure and dissociates, and the carboxylic acid compound bonds with the silicon oxide film (SiO₂) or silicon nitride film (SiN) to inhibit the etching of these films and protect them. Furthermore, the composition for etching silicon according to one embodiment of the present invention can maintain a uniform etch rate across the entire silicon film surface due to the alcohol-based additive.

Therefore, the composition for etching silicon according to one embodiment of the present invention can rapidly etch the silicon film while protecting the silicon oxide film (SiO₂) or silicon nitride film (SiN) used as a protective layer. It also exhibits excellent etching uniformity, enhancing the reliability of subsequent processes and thereby improving the quality and productivity of the manufactured semiconductor devices.

In one embodiment of the present invention, the silicon film may comprise polysilicon, that is, polycrystalline silicon.

The following describes in more detail the components of the etchant composition according to one embodiment of the present invention.

### Alkaline Compound (A)

In one embodiment of the present invention, the alkaline compound (A) serves to etch the silicon film.

The alkaline compound is a compound that dissociates in water to generate hydroxide anions (OH⁻)

Preferably, the alkaline compound may include a quaternary alkyl ammonium salt compound in terms of maintaining the etch rate for the silicon film.

The quaternary alkyl ammonium salt compound may be a quaternary alkyl ammonium hydroxide compound.

Specifically, the quaternary alkyl ammonium salt compound may be a compound of the following formula (1).

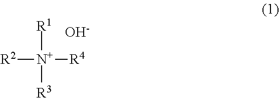

wherein,
R¹ to R⁴ are each independently C₁-C₆ alkyl.

The term “C₁-C₆ alkyl” as used herein means a straight-chain or branched monovalent hydrocarbon having 1 to 6 carbon atoms, and examples includes, but are not limited to, methyl, ethyl, n-propyl, i-propyl, n-butyl, i-butyl, t-butyl, n-pentyl, n-hexyl, and the like.

For example, the quaternary alkyl ammonium salt compound may be one or more selected from the group consisting of tetramethylammonium hydroxide, ethyl trimethylammonium hydroxide, diethyl dimethylammonium hydroxide, tetraethyl ammonium hydroxide, tetrapropylammonium hydroxide, tetrabutylammonium hydroxide, tetrapentylammonium hydroxide, and tetrahexylammonium hydroxide.

Preferably, the alkaline compound is a quaternary alkyl ammonium salt compound having four or more carbon atoms. The quaternary alkyl ammonium salt compound having four or more carbon atoms means that the total number of carbon atoms present within the compound is four or more.

If the number of carbon atoms is less than four, the etch rate of the silicon film decreases. If the number of carbon atoms exceeds twenty-four, the etch rate of the silicon film may also decrease.

The alkaline compound may be included in an amount of 0.1 to 10% by weight based on the total weight of the composition. If the content of the alkaline compound is below the above range, the etch rate of the silicon film may decrease, and if it exceeds the above range, damage to SiO₂ or SiN may occur, or the etching uniformity of the silicon film may deteriorate.

### Carboxylic Acid Compound (B)

In one embodiment of the present invention, the carboxylic acid compound (B) serves to protect the silicon oxide film (SiO₂) or silicon nitride film (SiN) used as a protective layer.

The carboxylic acid compound may be one or more of a carboxylic acid and a carboxylate salt.

The carboxylate salt is a compound formed by a carboxylate anion combining with a cation.

Examples of the cation include ammonium ions (NH₄⁺), quaternary alkyl ammonium ions, alkali metal ions, and the like.

The quaternary alkyl ammonium ion may be an ammonium ion having four C₁-C₆ alkyl groups, such as tetramethylammonium ion, tetraethyl ammonium ion, or tetrapropylammonium ion.

The alkali metal ions may include potassium ions (K⁺) and sodium ions (Na⁺)

Specifically, the carboxylic acid compound may be one or more selected from the group consisting of formic acid, acetic acid, propionic acid, butyric acid, palmitic acid, stearic acid, oleic acid, oxalic acid, malonic acid, succinic acid, tartaric acid, maleic acid, glycolic acid, glutaric acid, adipic acid, sulfosuccinic acid, valeric acid, caproic acid, caprylic acid, capric acid, lauric acid, myristic acid, lactic acid, malic acid, citric acid, benzoic acid, salicylic acid, naphthoic acid, nicotinic acid, toluic acid, anisic acid, cumic acid, phthalic acid, and salts thereof.

In one embodiment of the present invention, the carboxylic acid compound may have one or more hydroxyl groups in terms of its protective ability against SiO₂ or SiN.

For example, the carboxylic acid compound having one or more hydroxyl groups may be one or more selected from the group consisting of tartaric acid, glycolic acid, lactic acid, malic acid, citric acid, salicylic acid, and salts thereof.

The carboxylic acid compound may be included in an amount of 0.1 to 20% by weight based on the total weight of the composition. If the content of the carboxylic acid compound is below the above range, the etching prevention effect on SiO₂ or SiN may be reduced, and if it exceeds the above range, surface etching uniformity may deteriorate due to surface adsorption of the carboxylic acid compound, or the like.

### Alcohol-Based Additive (C)

In one embodiment of the present invention, the alcohol-based additive (C) serves to control surface etching uniformity.

The alcohol-based additive may be one or more selected from the group consisting of a monoalcohol having 1 to 4 carbon atoms, alkylene glycol ether having 2 to 4 carbon atoms, and alkylene glycol having 2 to 4 carbon atoms.

Examples of the monoalcohol having 1 to 4 carbon atoms include methanol, ethanol, propanol, butanol, etc., and these may be used alone or in combination of two or more.

Examples of the alkylene glycol ether having 2 to 4 carbon atoms include ethylene glycol monomethyl ether, propylene glycol monomethyl ether, butylene glycol monomethyl ether, etc., and these may be used alone or in combination of two or more.

Examples of the alkylene glycol having 2 to 4 carbon atoms include ethylene glycol, propylene glycol, butylene glycol, etc., and these can be used alone or in combination of two or more.

Preferably, the alcohol-based additive may be a monoalcohol having 1 to 4 carbon atoms, particularly methanol, in terms of controlling surface etching uniformity.

The alcohol-based additive may be included in an amount of 0.00001 to 0.1 wt %, preferably 0.0001 to 0.01 wt %, based on the total weight of the composition. If the content of the alcohol-based additive is below the above range, etching uniformity may not be secured, and if it exceeds the above range, the etch rate may decrease.

### Water (D)

Furthermore, the etchant composition according to one embodiment of the present invention may contain a residual amount of water to bring the total weight of the composition to 100 wt %. In the present invention, the water is not specifically limited, but deionized water for semiconductor processes is preferred, and deionized water having a resistivity value of 18 MΩ·cm or higher, indicating the degree to which ions have been removed from the water, is more preferred.

The term “residual amount” in the present invention refers to a residual amount such that the total weight of the composition, including the essential components of the present invention plus any additional components, is 100% by weight. The meaning of “residual amount” is not limited to compositions of the present invention that do not contain additional components.

A composition for etching silicon according to one embodiment of the present invention may include, based on the total weight of the composition, 0.1 to 10 wt % of an alkaline compound, 0.1 to 20 wt % of a carboxylic acid compound, and 0.00001 to 0.1 wt % of an alcohol-based additive, and it may contain a residual amount of water to bring the total weight of the composition to 100 wt %.

The composition for etching silicon according to one embodiment of the present invention may not contain an oxidizing agent.

If the composition for etching silicon contains an oxidizing agent, it may oxidize the surface of the silicon film, forming SiO₂, which may reduce the etch rate of the silicon film.

The oxidizing agents may include, for example, hydrogen peroxide (H₂O₂), nitric acid, periodic acid, ammonium peroxymonosulfate, ammonium chlorite (NH₄ClO₂), ammonium chlorate (NH₄ClO₃), ammonium iodate (NH₄IO₃), ammonium nitrate (NH₄NO₃), ammonium perborate (NH₄BO₃), ammonium perchlorate (NH₄ClO₄), ammonium periodate (NH₄IO₄), etc.

The composition for etching silicon according to one embodiment of the present invention may not contain a surfactant.

If the composition for etching silicon contains a surfactant, bubbles may form during the etching process, potentially reducing the etch rate due to interference with the etching of the silicon film.

The surfactants may include, for example, sodium dodecyl sulfate, hexadecylphosphonic acid, perfluorodecanoic acid, 2-(p-dodecylphenoxyethoxy)ethoxyethanol, hexadecyltrimethylammonium chloride, polyoxyethylene alkyl ether, polyoxyethylene aryl ether, polyoxyethylene alkenyl ether, polyoxyalkylene alkyl phenyl ether, polyoxyalkylene glycol, polyoxyethylene monoalkylate, bis-polyoxyethylene alkylamine, bis-polyoxyethylene alkylamide, alkylamine oxide, polyethylene glycol, polyoxyethylene glycol alkyl ether, octaethylene glycol monododecyl ether, pentaethylene glycol monododecyl ether, polyoxypropylene glycol alkyl ether, glucoside alkyl ether, decyl glucoside alkyl ether, lauryl glucoside alkyl ether, octyl glucoside alkyl ether, polyoxyethylene glycol alkyl phenol ether, sodium lauryl sulfate, benzalkonium chloride, etc.

The composition for etching silicon according to one embodiment of the present invention may not contain an azole compound.

If the composition for etching silicon contains an azole compound, the etch rate may decrease due to surface adsorption, and process impurities may occur.

The azole compounds may include, for example, benzotriazole (BTA), tolyl triazole, 5-methyl-benzotriazole (mBTA), 5-phenyl-benzotriazole, 5-nitro-benzotriazole, benzotriazole carboxylic acid, 3-amino-5-mercapto-1,2,4-triazole, 1-amino-1,2,4-triazole, hydroxybenzotriazole, 2-(5-amino-pentyl)-benzotriazole, 1-amino-1,2,3-triazole, 1-amino-5-methyl-1,2,3-triazole, 3-amino-1,2,4-triazole (3-ATA), 5-amino-1,2,4-triazole (5-ATA), 3-amino-5-methylthio-1H-1,2,4-triazole, 1,2,4-triazole (TAZ), etc.

The composition for etching silicon according to one embodiment of the present invention may not contain a thiol compound.

If the composition for etching silicon contains a thiol compound, the etch rate may decrease due to surface adsorption, and process impurities may occur.

The thiol compounds may include, for example, 3-mercapto-4-methyl-4H-1,2,4-triazole, 3-amino-1,2,4-triazole-5-thiol, 1H-1,2,4-triazole-3-thiol, etc.

The composition for etching silicon according to one embodiment of the present invention may not contain a fluoride.

If the composition for etching silicon contains a fluoride, it may increase etching damage to the protective film.

The fluoride may include, for example, ammonium fluoride, tetramethylammonium fluoride, ammonium bifluoride, H₂ZrF₆, H₂TiF₆, HPF₆, HF, tetrafluoroboric acid, hexafluorosilicic acid, tetrabutylammonium tetrafluoroborate (TBA-BF₄), ammonium hexafluorosilicate, ammonium hexafluorotitanate, etc.

Since chemical reactions occur in the silicon film in an alkaline environment, causing the silicon film to be removed, the composition for etching silicon according to one embodiment of the present invention may have a pH exceeding 7 at 25° C., preferably 10 or higher, for example 10 to 14, and more preferably 12 or higher, for example 12 to 14

The components used in the etchant composition according to one embodiment of the present invention can be manufactured by conventionally known methods and preferably have a purity suitable for semiconductor processes.

The etchant composition according to one embodiment of the present invention can be very usefully employed in the semiconductor manufacturing process for selectively wet-etching silicon films used in the STI (Shallow Trench Isolation) or gate electrode formation process of DRAM or NAND flash memory.

Therefore, one embodiment of the present invention relates to a method for forming a pattern comprising a step of etching a silicon film using the aforementioned composition for etching silicon.

The silicon film can be formed using an LPCVD (Low Pressure Chemical Vapor Deposition) device by first introducing an inert gas such as N₂ or He into the process tube before introducing the process gas, and then introducing the process gas SiH₄, which is the silicon source for polysilicon deposition.

The method for forming a pattern according to one embodiment of the present invention can form a pattern according to a conventional pattern formation method, except for the use of the aforementioned composition for etching silicon.

For example, methods using immersion, spraying, or immersion and spraying may be employed in batch-type etching devices or single-type etching devices.

STI or gate electrodes for DRAM or NAND flash memory can be formed by the method for forming a pattern according to one embodiment of the present invention, for example.

One embodiment of the present invention relates to a semiconductor device comprising a silicon film etched by the aforementioned composition for etching silicon. For example, the semiconductor device of the present invention may be a DRAM or NAND flash memory device.

Hereinafter, the present invention will be described more specifically by means of Examples, Comparative Examples, and Experimental Examples. These Examples, Comparative Examples, and Experimental Examples are intended to illustrate the present invention only, and it is obvious to those skilled in the art that the scope of the present invention is not limited to them.

### EXAMPLES AND COMPARATIVE EXAMPLES: PREPARATION OF COMPOSITION FOR ETCHING SILICON

Compositions for etching silicon were prepared by mixing the components as shown in Table 1 and Table 2 (unit: wt %) below.

TABLE 1

| | | | Carboxylic acid | | | | | |
|---|---|---|---|---|---|---|---|---|
| | Alkaline compound | | compound | | Additive | | | |
| | | Content | | Content | | Content | | |
| | Compound | (wt %) | Compound | (wt %) | Compound | (wt %) | Water | pH |
| Example 1 | 1-A | 0.05 | 2-A | 3 | methanol | 0.002 | residual | 12.1 |
| Example 2 | 1-A | 0.1 | 2-A | 3 | methanol | 0.002 | residual | 12.4 |
| Example 3 | 1-A | 2.5 | 2-A | 3 | methanol | 0.002 | residual | 14 |
| Example 4 | 1-A | 5 | 2-A | 3 | methanol | 0.002 | residual | 14 |
| Example 5 | 1-A | 10 | 2-A | 3 | methanol | 0.002 | residual | 14 |
| Example 6 | 1-A | 11.5 | 2-A | 3 | methanol | 0.002 | residual | 14 |
| Example 7 | 1-A | 8 | 2-A | 0.05 | methanol | 0.002 | residual | 14 |
| Example 8 | 1-A | 8 | 2-A | 0.1 | methanol | 0.002 | residual | 14 |
| Example 9 | 1-A | 8 | 2-A | 5 | methanol | 0.002 | residual | 14 |
| Example 10 | 1-A | 8 | 2-A | 10 | methanol | 0.002 | residual | 14 |
| Example 11 | 1-A | 8 | 2-A | 20 | methanol | 0.002 | residual | 14 |
| Example 12 | 1-A | 8 | 2-A | 20.5 | methanol | 0.002 | residual | 14 |
| Example 13 | 1-A | 8 | 2-A | 3 | methanol | 0.000005 | residual | 14 |
| Example 14 | 1-A | 8 | 2-A | 3 | methanol | 0.00001 | residual | 14 |
| Example 15 | 1-A | 8 | 2-A | 3 | methanol | 0.0001 | residual | 14 |
| Example 16 | 1-A | 8 | 2-A | 3 | methanol | 0.01 | residual | 14 |
| Example 17 | 1-A | 8 | 2-A | 3 | methanol | 0.1 | residual | 14 |
| Example 18 | 1-A | 8 | 2-A | 3 | methanol | 0.15 | residual | 14 |
| Example 19 | 1-B | 0.05 | 2-B | 3 | methanol | 0.002 | residual | 12.1 |
| Example 20 | 1-B | 0.1 | 2-B | 3 | methanol | 0.002 | residual | 12.4 |
| Example 21 | 1-B | 2.5 | 2-B | 3 | methanol | 0.002 | residual | 14 |
| Example 22 | 1-B | 5 | 2-B | 3 | methanol | 0.002 | residual | 14 |
| Example 23 | 1-B | 10 | 2-B | 3 | methanol | 0.002 | residual | 14 |
| Example 24 | 1-B | 11.5 | 2-B | 35 | methanol | 0.002 | residual | 14 |
| Example 25 | 1-B | 8 | 2-B | 0.05 | methanol | 0.002 | residual | 14 |
| Example 26 | 1-B | 8 | 2-B | 0.1 | methanol | 0.002 | residual | 14 |
| Example 27 | 1-B | 8 | 2-B | 5 | methanol | 0.002 | residual | 14 |
| Example 28 | 1-B | 8 | 2-B | 10 | methanol | 0.002 | residual | 14 |
| Example 29 | 1-B | 8 | 2-B | 20 | methanol | 0.002 | residual | 14 |
| Example 30 | 1-B | 8 | 2-B | 20.5 | methanol | 0.002 | residual | 14 |
| Example 31 | 1-B | 8 | 2-B | 3 | methanol | 0.000005 | residual | 14 |
| Example 32 | 1-B | 8 | 2-B | 3 | methanol | 0.00001 | residual | 14 |
| Example 33 | 1-B | 8 | 2-B | 3 | methanol | 0.0001 | residual | 14 |
| Example 34 | 1-B | 8 | 2-B | 3 | methanol | 0.01 | residual | 14 |
| Example 35 | 1-B | 8 | 2-B | 3 | methanol | 0.1 | residual | 14 |
| Example 36 | 1-B | 8 | 2-B | 3 | methanol | 0.15 | residual | 14 |
| Example 37 | 1-A | 8 | 2-C | 3 | methanol | 0.002 | residual | 14 |
| Example 38 | 1-B | 8 | 2-C | 3 | methanol | 0.002 | residual | 14 |
| Example 39 | 1-C | 8 | 2-C | 3 | methanol | 0.002 | residual | 14 |
| Example 40 | 1-D | 8 | 2-C | 3 | methanol | 0.002 | residual | 14 |
| Example 41 | 1-E | 8 | 2-C | 3 | methanol | 0.002 | residual | 14 |
| Example 42 | 1-F | 8 | 2-C | 3 | methanol | 0.002 | residual | 14 |
| Example 43 | 1-G | 8 | 2-C | 3 | methanol | 0.002 | residual | 14 |
| Example 44 | 1-H | 8 | 2-C | 3 | methanol | 0.002 | residual | 14 |
| Example 45 | 1-A | 8 | 2-D | 3 | methanol | 0.002 | residual | 14 |
| Example 46 | 1-A | 8 | 2-E | 3 | methanol | 0.002 | residual | 14 |
| Example 47 | 1-A | 8 | 2-F | 3 | methanol | 0.002 | residual | 14 |
| Example 48 | 1-A | 8 | 2-G | 3 | methanol | 0.002 | residual | 14 |
| Example 49 | 1-A | 8 | 2-H | 3 | methanol | 0.002 | residual | 14 |
| Example 50 | 1-A | 8 | 2-I | 3 | methanol | 0.002 | residual | 14 |
| Example 51 | 1-A | 8 | 2-J | 3 | methanol | 0.002 | residual | 14 |
| Example 52 | 1-A | 8 | 2-K | 3 | methanol | 0.002 | residual | 14 |
| Example 53 | 1-A | 8 | 2-L | 3 | methanol | 0.002 | residual | 14 |
| Example 54 | 1-A | 8 | 2-C | 3 | ethanol | 0.002 | residual | 14 |
| Example 55 | 1-A | 8 | 2-C | 3 | propanol | 0.002 | residual | 14 |
| Example 56 | 1-A | 8 | 2-C | 3 | butanol | 0.002 | residual | 14 |
| Example 57 | 1-A | 8 | 2-C | 3 | ethylene | 0.002 | residual | 14 |
| | | | | | glycol | | | |
| | | | | | monomethyl | | | |
| | | | | | ether | | | |
| Example 58 | 1-A | 8 | 2-C | 3 | ethylene | 0.002 | residual | 14 |
| | | | | | glycol | | | |

TABLE 2

| | | | Carboxylic acid | | | | | | | |
|---|---|---|---|---|---|---|---|---|---|---|
| | Alkaline compound | | compound | | Additive | | Other | | | |
| | | Content | | Content | | Content | | Content | | |
| | Compound | (wt %) | Compound | (wt %) | Compound | (wt %) | Compound | (wt %) | Water | pH |
| Comparative | | | 2-A | 3 | methanol | 0.002 | | | residual | 6 |
| Example 1 | | | | | | | | | | |
| Comparative | 1-A | 8 | | | methanol | 0.002 | | | residual | 14 |
| Example 2 | | | | | | | | | | |
| Comparative | 1-A | 8 | 2-A | 3 | | | | | residual | 14 |
| Example 3 | | | | | | | | | | |
| Comparative | | | 2-A | 3 | methanol | 0.002 | PGMEA | 10 | residual | 6 |
| Example 4 | | | | | | | | | | |
| Comparative | 1-A | 8 | | | methanol | 0.002 | PGME | 10 | residual | 14 |
| Example 5 | | | | | | | | | | |
| Comparative | 1-A | 8 | 2-A | 3 | | | THF | 10 | residual | 14 |
| Example 6 | | | | | | | | | | |
| Comparative | 1-A | 8 | | | methanol | 0.002 | IPA | 10 | residual | 14 |
| Example 7 | | | | | | | | | | |
| Comparative | | | 2-A | 3 | methanol | 0.002 | acetone | 10 | residual | 6 |
| Example 8 | | | | | | | | | | |
| Comparative | 1-A | 8 | | | methanol | 0.002 | DMSO | 10 | residual | 14 |
| Example 9 | | | | | | | | | | |
| Comparative | 1-A | 8 | 2-A | 3 | methanol | 0.002 | H₂O₂ | 5 | residual | 14 |
| Example 10 | | | | | | | | | | |
| Comparative | 1-A | 8 | 2-A | 3 | methanol | 0.002 | NaOH | 10 | residual | 14 |
| Example 11 | | | | | | | | | | |
| Comparative | 1-A | 8 | 2-A | 3 | methanol | 0.002 | BTA | 10 | residual | 14 |
| Example 12 | | | | | | | | | | |
| Comparative | 1-A | 8 | 2-A | 3 | methanol | 0.002 | 1H-1,2,4- | 10 | residual | 14 |
| Example 13 | | | | | | | triazole-3- | | | |
| | | | | | | | thiol | | | |
| Comparative | 1-A | 8 | 2-B | 3 | methanol | 0.002 | sodium | 10 | residual | 14 |
| Example 14 | | | | | | | dodecyl | | | |
| | | | | | | | sulfate | | | |
| Comparative | 1-A | 8 | 2-B | 3 | methanol | 0.002 | hexadecyl | 10 | residual | 14 |
| Example 15 | | | | | | | phosphonic | | | |
| | | | | | | | acid | | | |
| Comparative | 1-A | 8 | 2-C | 3 | methanol | 0.002 | perfluoro | 10 | residual | 14 |
| Example 16 | | | | | | | decanoic | | | |
| | | | | | | | acid | | | |
| Comparative | 1-A | 8 | 2-D | 3 | methanol | 0.002 | 2-(p-dodecyl- | 10 | residual | 14 |
| Example 17 | | | | | | | phenoxyethoxy)- | | | |
| | | | | | | | ethoxyethanol | | | |
| Comparative | 1-B | 8 | 2-A | 3 | methanol | 0.002 | hexadecyltri- | 10 | residual | 14 |
| Example 18 | | | | | | | methylammonium | | | |
| | | | | | | | chloride | | | |
| Comparative | 1-A | 8 | 2-A | 3 | methanol | 0.002 | ammonium | 3 | residual | 14 |
| Example 19 | | | | | | | fluoride | | | |
| Comparative | 1-A | 8 | 2-A | 3 | methanol | 0.002 | tetramethyl- | 3 | residual | 14 |
| Example 20 | | | | | | | ammonium | | | |
| | | | | | | | fluoride | | | |
| Comparative | 1-A | 8 | 2-A | 3 | methanol | 0.002 | ammonium | 3 | residual | 14 |
| Example 21 | | | | | | | bifluoride | | | |

1-A: TMAH (Tetramethylammonium hydroxide)
1-B: ETMAH (Ethyltrimethylammonium hydroxide)
1-C: DEDMAH (Diethyldimethylammonium hydroxide)
1-D: TEAH (Tetraethylammonium hydroxide)
1-E: TPRAH (Tetrapropylammonium hydroxide)
1-F: TBAH (Tetrabutylammonium hydroxide)
1-G: TPEAH (Tetrapentylammonium hydroxide)
1-H: THAH (Tetrahexylammonium hydroxide)
2-A: Ammonium oxalate
2-B: Ammonium citrate
2-C: Oxalic acid
2-D: Acetic acid
2-E: Citric acid
2-F: Formic acid
2-G: Ammonium malate
2-H: Tartaric acid
2-I: Lactic acid
2-J: Tetramethylammonium citrate
2-K: Tetraethylammonium acetate
2-L: Potassium lactate

### Experimental Example 1

The etchant compositions of the above prepared Examples and Comparative Examples were evaluated for etch rate and selectivity of the silicon film, surface roughness characteristics after etching, and etch rate retention of the silicon film by the following methods, and the results are shown in Table 3 and Table 4 below.

### (1) Etch Rate and Selectivity of Silicon Films

Specimens were prepared by cutting a silicon wafer on which polysilicon (poly Si) was deposited to a thickness of 2000 Å into a size of 1.5×1.5 cm. Additionally, a silicon oxide (SiO₂) wafer and a silicon nitride (SiN) wafer were each cut into a size of 1.5×1.5 cm to prepare specimens. These specimens were immersed in the etchant compositions of the above Examples and Comparative Examples at 70° C. and 400 rpm. Poly Si was immersed for 30 seconds, while the SiO₂ and SiN films were immersed for 5000 seconds. Subsequently, the specimens were removed, rinsed with water, dried using air, and the silicon film thickness was measured using an ellipsometer. Next, the etch rates for the poly Si, SiO₂, and SiN films were calculated from the respective film thickness change values. In addition, the selectivity was determined by comparing the etch rates of the SiN and SiO₂ films to that of the polysilicon.

The poly Si etch rate, poly Si/SiO₂ selectivity, and poly Si/SiN selectivity are shown according to the following evaluation criteria.

### <Poly Si Etch Rate Evaluation Criteria>

Level 1: Less than 5 Å/sec
Level 2: 5 Å/sec or more and less than 10 Å/sec
Level 3: 10 Å/sec or more and less than 20 Å/sec
Level 4: 20 Å/sec or more and less than 30 Å/sec
Level 5: 30 Å/sec or more and less than 40 Å/sec
Level 6: 40 Å/sec or more

### <Poly Si/SiO₂ Selectivity Evaluation Criteria>

Level 1: Below 4000
Level 2: 4000 or above and below 8000
Level 3: 8000 or above and below 15000
Level 4: 15000 or above

### <Poly Si/SiN Selectivity Evaluation Criteria>

Level 1: Below 2000
Level 2: 2000 or above and below 3000
Level 3: 3000 or above and below 4000
Level 4: 4000 or above and below 5000
Level 5: 5000 or above
   (2) Surface Roughness Characteristics after Etching

Specimens were prepared by cutting a silicon wafer on which polysilicon was deposited to a thickness of 2000 Å into a size of 1.5×1.5 cm. These specimens were immersed in the etchant compositions of the above Examples and Comparative Examples at 70° C. and 400 rpm. Poly Si immersion was performed for 40 seconds. Subsequently, the specimens were removed, rinsed with water, and dried using air. Thereafter, the surface roughness was measured as the root-mean-square (rms) roughness (nm) using an atomic force microscope (AFM).

Surface roughness characteristics were indicated according to the following evaluation criteria. If the polysilicon etch rate was Level 2 or lower, or if the selectivity between polysilicon and silicon oxide, or the selectivity between polysilicon and silicon nitride film was Level 1, it was indicated as ‘-’ because there was no need to measure the surface roughness after etching.

### <Surface Roughness Evaluation Criteria>

⊚: Less than 2 nm
Δ: 2 nm or more and less than 3 nm
x: 3 nm or more

### (3) Etch Rate Retention of Silicon Film

Specimens were prepared by cutting a silicon wafer on which polysilicon was deposited to a thickness of 2000 Å into a size of 1.5×1.5 cm. Silicon powder was added to the etchant compositions of the above Examples and Comparative Examples at a concentration of 1000 ppm, and the specimens were then immersed at 70° C. and 400 rpm for 30 seconds. The etch rate reduction was calculated relative to the polysilicon etch rate in the composition without added silicon powder.

The etch rate retention of silicon film was indicated according to the following evaluation criteria. If the polysilicon etch rate was Level 2 or lower, or if the selectivity between polysilicon and silicon oxide, or the selectivity between polysilicon and silicon nitride film was Level 1, it was indicated as ‘-’ because there was no need to measure the polysilicon etch rate retention.

### <Evaluation Criteria of Etch Rate Retention of Silicon Film>

⊚: Less than 30%
Δ: 30% or more and less than 50%
x: 50% or more

TABLE 3

| | | | Selectivity of | Surface roughness | Etch rate |
|---|---|---|---|---|---|
| | Etch rate of poly | Selectivity of poly | poly Si/SiN | characteristics | retention |
| | Si (level) | Si/SiO₂ (level) | (level) | after etching | of poly Si |
| Example 1 | 4 | 2 | 2 | ⊚ | ⊚ |
| Example 2 | 5 | 2 | 3 | ⊚ | ⊚ |
| Example 3 | 6 | 2 | 3 | ⊚ | ⊚ |
| Example 4 | 6 | 2 | 3 | ⊚ | ⊚ |
| Example 5 | 6 | 1 | 3 | ⊚ | ⊚ |
| Example 6 | 5 | 1 | 2 | Δ | ⊚ |
| Example 7 | 6 | 1 | 1 | ⊚ | ⊚ |
| Example 8 | 6 | 2 | 2 | ⊚ | ⊚ |
| Example 9 | 6 | 2 | 3 | ⊚ | ⊚ |
| Example 10 | 6 | 2 | 3 | ⊚ | ⊚ |
| Example 11 | 5 | 2 | 3 | ⊚ | ⊚ |
| Example 12 | 4 | 3 | 3 | Δ | ⊚ |
| Example 13 | 6 | 2 | 3 | Δ | ⊚ |
| Example 14 | 6 | 2 | 3 | Δ | ⊚ |
| Example 15 | 6 | 2 | 3 | ⊚ | ⊚ |
| Example 16 | 6 | 2 | 3 | ⊚ | ⊚ |
| Example 17 | 5 | 2 | 3 | ⊚ | ⊚ |
| Example 18 | 4 | 3 | 3 | ⊚ | ⊚ |
| Example 19 | 3 | 3 | 3 | ⊚ | ⊚ |
| Example 20 | 4 | 3 | 3 | ⊚ | ⊚ |
| Example 21 | 5 | 3 | 3 | ⊚ | ⊚ |
| Example 22 | 5 | 3 | 3 | ⊚ | ⊚ |
| Example 23 | 5 | 2 | 3 | ⊚ | ⊚ |
| Example 24 | 4 | 2 | 2 | Δ | ⊚ |
| Example 25 | 5 | 1 | 2 | ⊚ | ⊚ |
| Example 26 | 5 | 3 | 3 | ⊚ | ⊚ |
| Example 27 | 5 | 3 | 3 | ⊚ | ⊚ |
| Example 28 | 5 | 3 | 3 | ⊚ | ⊚ |
| Example 29 | 4 | 3 | 3 | ⊚ | ⊚ |
| Example 30 | 3 | 3 | 3 | Δ | ⊚ |
| Example 31 | 5 | 3 | 3 | Δ | ⊚ |
| Example 32 | 5 | 3 | 3 | Δ | ⊚ |
| Example 33 | 5 | 3 | 3 | ⊚ | ⊚ |
| Example 34 | 5 | 3 | 3 | ⊚ | ⊚ |
| Example 35 | 4 | 3 | 3 | ⊚ | ⊚ |
| Example 36 | 3 | 3 | 3 | ⊚ | ⊚ |
| Example 37 | 4 | 3 | 3 | ⊚ | ⊚ |
| Example 38 | 4 | 2 | 3 | ⊚ | ⊚ |
| Example 39 | 4 | 3 | 3 | ⊚ | ⊚ |
| Example 40 | 4 | 2 | 3 | ⊚ | ⊚ |
| Example 41 | 4 | 2 | 3 | ⊚ | ⊚ |
| Example 42 | 4 | 2 | 3 | ⊚ | ⊚ |
| Example 43 | 4 | 2 | 3 | ⊚ | ⊚ |
| Example 44 | 4 | 2 | 3 | ⊚ | ⊚ |
| Example 45 | 5 | 2 | 3 | ⊚ | ⊚ |
| Example 46 | 6 | 3 | 3 | ⊚ | ⊚ |
| Example 47 | 5 | 2 | 2 | Δ | Δ |
| Example 48 | 5 | 2 | 2 | Δ | ⊚ |
| Example 49 | 5 | 2 | 3 | ⊚ | Δ |
| Example 50 | 5 | 3 | 3 | ⊚ | ⊚ |
| Example 51 | 6 | 3 | 3 | ⊚ | ⊚ |
| Example 52 | 5 | 2 | 2 | Δ | ⊚ |
| Example 53 | 5 | 3 | 3 | ⊚ | ⊚ |
| Example 54 | 5 | 2 | 3 | ⊚ | ⊚ |
| Example 55 | 5 | 2 | 3 | Δ | ⊚ |
| Example 56 | 4 | 2 | 3 | Δ | ⊚ |
| Example 57 | 4 | 2 | 3 | Δ | ⊚ |
| Example 58 | 4 | 2 | 3 | Δ | ⊚ |

TABLE 4

| | | | Selectivity of | Surface roughness | Etch rate |
|---|---|---|---|---|---|
| | Etch rate of poly | Selectivity of poly | poly Si/SiN | characteristics | retention |
| | Si (level) | Si/SiO₂ (level) | (level) | after etching | of poly Si |
| Comparative | 1 | 1 | 1 | — | — |
| Example 1 | | | | | |
| Comparative | 6 | 1 | 1 | — | — |
| Example 2 | | | | | |
| Comparative | 6 | 2 | 3 | X | ⊚ |
| Example 3 | | | | | |
| Comparative | 1 | 1 | 1 | — | — |
| Example 4 | | | | | |
| Comparative | 3 | 2 | 1 | — | — |
| Example 5 | | | | | |
| Comparative | 3 | 2 | 1 | Δ | X |
| Example 6 | | | | | |
| Comparative | 4 | 1 | 1 | — | — |
| Example 7 | | | | | |
| Comparative | 1 | 1 | 1 | — | — |
| Example 8 | | | | | |
| Comparative | 1 | 1 | 1 | — | — |
| Example 9 | | | | | |
| Comparative | 1 | 1 | 1 | — | — |
| Example 10 | | | | | |
| Comparative | 3 | 2 | 2 | Δ | X |
| Example 11 | | | | | |
| Comparative | 2 | 2 | 3 | — | — |
| Example 12 | | | | | |
| Comparative | 2 | 1 | 1 | — | — |
| Example 13 | | | | | |
| Comparative | 1 | 1 | 1 | — | — |
| Example 14 | | | | | |
| Comparative | 2 | 1 | 2 | — | — |
| Example 15 | | | | | |
| Comparative | 2 | 2 | 2 | — | — |
| Example 16 | | | | | |
| Comparative | 1 | 1 | 1 | — | — |
| Example 17 | | | | | |
| Comparative | 3 | 1 | 2 | — | — |
| Example 18 | | | | | |
| Comparative | 3 | 1 | 1 | — | — |
| Example 19 | | | | | |
| Comparative | 3 | 1 | 1 | — | — |
| Example 20 | | | | | |
| Comparative | 3 | 1 | 1 | — | — |
| Example 21 | | | | | |

As shown in Table 3 above, the compositions for etching silicon of Examples 1 to 58, which include an alkaline compound, a carboxylic acid compound, an alcohol-based additive, and water, were confirmed to rapidly etch the silicon film while protecting SiO₂ and SiN, exhibit excellent etching uniformity, and maintain an excellent etch rate retention of the silicon film.

On the other hand, as shown in Table 4, the compositions for etching silicon of Comparative Examples 1 to 9, which do not contain at least one of the alkaline compound, carboxylic acid compound, or alcohol-based additive, exhibit slow etch rates of the silicon film, poor protective capabilities for SiO₂ and/or SiN, i.e., poor selectivity for poly Si/SiO₂ and/or poor selectivity for poly Si/SiN, reduced etching uniformity, or poor etch rate retention of the silicon film.

Meanwhile, it can be seen that the etchant composition of Comparative Example 10, which contains an oxidizing agent, and the etchant compositions of Comparative Examples 14 to 18, which contain surfactants, exhibit reduced etch rates for the silicon film.

The etchant composition of Comparative Example 12, which contains an azole compound, and the etchant composition of Comparative Example 13, which contains a thiol compound, also exhibited reduced etch rates for the silicon film and were found to generate process impurities.

The etchant compositions in Comparative Examples 19 to 21, which contain fluorides, exhibit increased etching damage to the protective film, resulting in poor selectivity for both poly Si/SiO₂ and poly Si/SiN.

Although particular embodiments of the present invention have been shown and described, it will be understood by those skilled in the art that it is not intended to limit the present invention to the preferred embodiments, and it will be obvious to those skilled in the art that various changes and modifications may be made without departing from the spirit and scope of the invention.

The scope of the present invention, therefore, is to be defined by the appended claims and equivalents thereof.

1. A composition for etching silicon comprising an alkaline compound, a carboxylic acid compound, an alcohol-based additive, and water.

2. The composition for etching silicon according to claim 1, wherein the alkaline compound comprises a quaternary alkyl ammonium salt compound.

3. The composition for etching silicon according to claim 2, wherein the quaternary alkyl ammonium salt compound is one or more selected from the group consisting of tetramethylammonium hydroxide, ethyl trimethylammonium hydroxide, diethyl dimethylammonium hydroxide, tetraethyl ammonium hydroxide, tetrapropylammonium hydroxide, tetrabutylammonium hydroxide, tetrapentylammonium hydroxide, and tetrahexylammonium hydroxide.

4. The composition for etching silicon according to claim 1, wherein the carboxylic acid compound is one or more selected from the group consisting of formic acid, acetic acid, propionic acid, butyric acid, palmitic acid, stearic acid, oleic acid, oxalic acid, malonic acid, succinic acid, tartaric acid, maleic acid, glycolic acid, glutaric acid, adipic acid, sulfosuccinic acid, valeric acid, caproic acid, caprylic acid, capric acid, lauric acid, myristic acid, lactic acid, malic acid, citric acid, benzoic acid, salicylic acid, naphthoic acid, nicotinic acid, toluic acid, anisic acid, cumic acid, phthalic acid, and salts thereof.

5. The composition for etching silicon according to claim 1, wherein the carboxylic acid compound has one or more hydroxyl groups.

6. The composition for etching silicon according to claim 1, wherein the alcohol-based additive is one or more selected from the group consisting of a monoalcohol having 1 to 4 carbon atoms, alkylene glycol ether having 2 to 4 carbon atoms, and alkylene glycol having 2 to 4 carbon atoms.

7. The composition for etching silicon according to claim 1, wherein the composition comprises 0.1 to 10 wt % of the alkaline compound, 0.1 to 20 wt % of the carboxylic acid compound, 0.00001 to 0.1 wt % of the alcohol-based additive, based on the total weight of the composition, and a residual amount of water to bring the total weight of the composition to 100 wt %.

8. The composition for etching silicon according to claim 1, wherein the composition does not contain an oxidizing agent.

9. The composition for etching silicon according to claim 1, wherein the composition does not contain a surfactant.

10. The composition for etching silicon according to claim 1, wherein the composition does not contain an azole compound.

11. The composition for etching silicon according to claim 1, wherein the composition does not contain a thiol compound.

12. The composition for etching silicon according to claim 1, wherein the composition does not contain a fluoride.

13. The composition for etching silicon according to claim 1, wherein the composition has a pH of 10 or higher at 25° C.

14. A method for forming a pattern comprising etching a silicon film using the composition for etching silicon according to claim 1.
